(19) United States
(12) Patent Application Publication
(10) Pub. No.: US 2025/0077737 A1
(43) Pub. Date: Mar. 6, 2025

(54) DATA RECORDING SYSTEMS, DEVICES, AND METHODS

(71) Applicant: The Florida State University Research Foundation, Inc., Tallahassee, FL (US)

(72) Inventors: Mark Stanovich, Tallahassee, FL (US); James Langston, Tallahassee, FL (US)

(21) Appl. No.: 18/823,114

(22) Filed: Sep. 3, 2024

Related U.S. Application Data
(60) Provisional application No. 63/535,816, filed on Aug. 31, 2023.

(51) Int. Cl. G06F 30/20

(52) U.S. Cl. CPC G06F 30/20

(57) ABSTRACT

An example data recorder includes a field programmable gate array (FPGA) operably coupled to a power system simulator where the FPGA is configured to record an output of the power system simulator to a data file. The example data recorder further includes a server operably coupled to the field programmable gate array, where the server is configured to receive the data file from the FPGA and store the data file. An example system for analyzing a power system includes a power system simulator, an FPGA operably coupled to the power system simulator, the FPGA configured to record an output of the power system simulator to a data file, and a server operably coupled to the field programmable gate array; where server is configured to receive the data file from the FPGA and store the data file.

### CROSS-REFERENCE TO RELATED APPLICATIONS

This Application claims priority to, and benefit under 35 U.S.C. § 119(e) of, U.S. Provisional Patent Application No. 63/535,816, filed Aug. 31, 2023, which is hereby incorporated by reference herein in its entirety as if fully set forth below.

### STATEMENT REGARDING FEDERALLY FUNDED RESEARCH

This invention was made with government support under N000141410198 awarded by the Office of Naval Research. The government has certain rights in the invention.

### BACKGROUND

Power systems include electrical transmission equipment (e.g., power lines), motors, generators, power electronics (e.g., power supplies) and other devices that are used to generate, transmit, store, and use electrical power. These power systems can be modeled for research, development, and safety testing. Models of power systems can be performed using specialized hardware power system models. Some models of power systems include hardware devices that are optimized to simulate the dynamics of electrical machines. Both power systems and models of power systems can be difficult to record data from due to the large amount of data recorded and the small timescales that can be used in the simulations.

### SUMMARY

In some aspects, the techniques described herein relate to a data recorder, including: a field programmable gate array (FPGA) operably coupled to a power system simulator; the FPGA configured to record an output of the power system simulator to a data file; and a server operably coupled to the field programmable gate array; wherein the server is configured to receive the data file from the FPGA and store the data file.

In some aspects, the techniques described herein relate to a data recorder, wherein the power system simulator is a real-time digital simulator (RTDS).

In some aspects, the techniques described herein relate to a data recorder, wherein the power system simulator is configured to perform a real-time hardware simulation.

In some aspects, the techniques described herein relate to a data recorder, wherein the FPGA is operably coupled to the power system simulator by a fiber optic cable.

In some aspects, the techniques described herein relate to a data recorder, wherein the FPGA is operably coupled to the server by an ethernet cable.

In some aspects, the techniques described herein relate to a data recorder, further including a workstation, wherein the workstation is operably coupled to the server.

In some aspects, the techniques described herein relate to a data recorder, wherein the FPGA is configured to record a frame based on a signal from the server.

In some aspects, the techniques described herein relate to a data recorder, wherein a delay between consecutive frames is 50 microseconds or less.

In some aspects, the techniques described herein relate to a data recorder, wherein the FPGA is configured to output a representation of the frame to a display.

In some aspects, the techniques described herein relate to a data recorder, wherein the server includes a multi-threaded processor configured to simultaneously log data, communicate with the FPGA, and process the data file.

In some aspects, the techniques described herein relate to a data recorder, wherein a hardware component is operably coupled to the power system simulator.

In some aspects, the techniques described herein relate to a system including: a power system simulator; a field programmable gate array (FPGA) operably coupled to the power system simulator; the FPGA configured to record an output of the power system simulator to a data file; and a server operably coupled to the field programmable gate array; wherein the server is configured to receive the data file from the FPGA and store the data file.

In some aspects, the techniques described herein relate to a system, wherein the power system simulator is a real-time digital simulator (RTDS).

In some aspects, the techniques described herein relate to a system, wherein the power system simulator is configured to perform a real-time hardware simulation.

In some aspects, the techniques described herein relate to a system, wherein the FPGA is operably coupled to the power system simulator by a fiber optic cable.

In some aspects, the techniques described herein relate to a system, wherein the FPGA is operably coupled to the server by an ethernet cable.

In some aspects, the techniques described herein relate to a system, further including a workstation, wherein the workstation is operably coupled to the server.

In some aspects, the techniques described herein relate to a system, wherein the FPGA is configured to record a frame based on a signal from the server.

In some aspects, the techniques described herein relate to a system, wherein a delay between consecutive frames is 50 microseconds or less.

In some aspects, the techniques described herein relate to a system, further including outputting a representation of the frame to a display.

In some aspects, the techniques described herein relate to a system, wherein the server includes a multi-threaded processor configured to simultaneously log data, communicate with the FPGA, and process the data file.

In some aspects, the techniques described herein relate to a system, further including a hardware component operably coupled to the power system simulator.

It should be understood that the above-described subject matter may also be implemented as a computer-controlled apparatus, a computer process, a computing system, or an article of manufacture, such as a computer-readable storage medium.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The components in the drawings are not necessarily to scale relative to each other. Like reference numerals designate corresponding parts throughout the several views.

FIG. 1 is a system block diagram of a system and data recorder according to an implementation of the present disclosure.

FIG. 2 illustrates an example computing device.

FIG. 3 illustrates an example power system simulator, according to an implementation of the present disclosure.

FIG. 4 illustrates an example controller-hardware-in-loop configuration (CHIL), according to an implementation of the present disclosure.

FIG. 5A illustrates a conventional CHIL configuration.

FIG. 5B illustrates a surrogate CHIL configuration, according to an implementation of the present disclosure.

FIG. 6 illustrates an example 5MW dynamometer and gear box used in a study of an example implementation of the present disclosure.

FIG. 7 illustrates an example plot of RPM over time for the 5MW dynamometer and gear box illustrated in FIG. 6.

FIG. 8 illustrates an example system overview for a study of an example implementation of the present disclosure.

FIG. 9 illustrates an example an example schematic of a logger, according to an implementation of the present disclosure.

FIG. 10 illustrates an example system for fiber to ethernet conversion, according to implementations of the present disclosure.

FIG. 11 illustrates an example communication protocol that can be used in implementations of the present disclosure.

### DETAILED DESCRIPTION

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. While implementations will be described for data recording of power systems and simulated power systems, it will become evident to those skilled in the art that the implementations are not limited thereto, but are applicable to measuring other electronics.

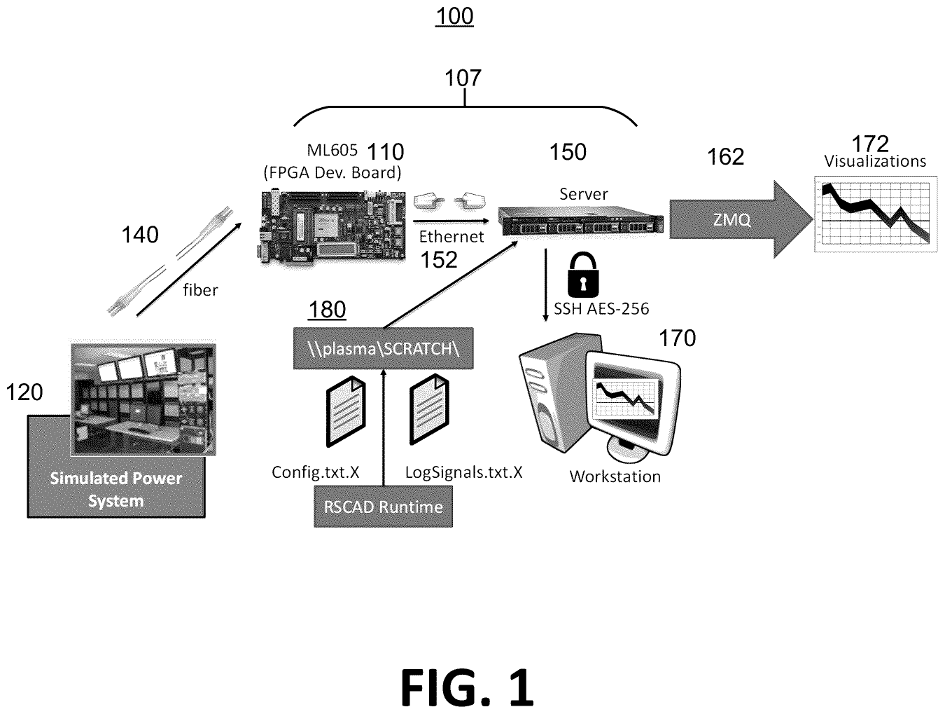

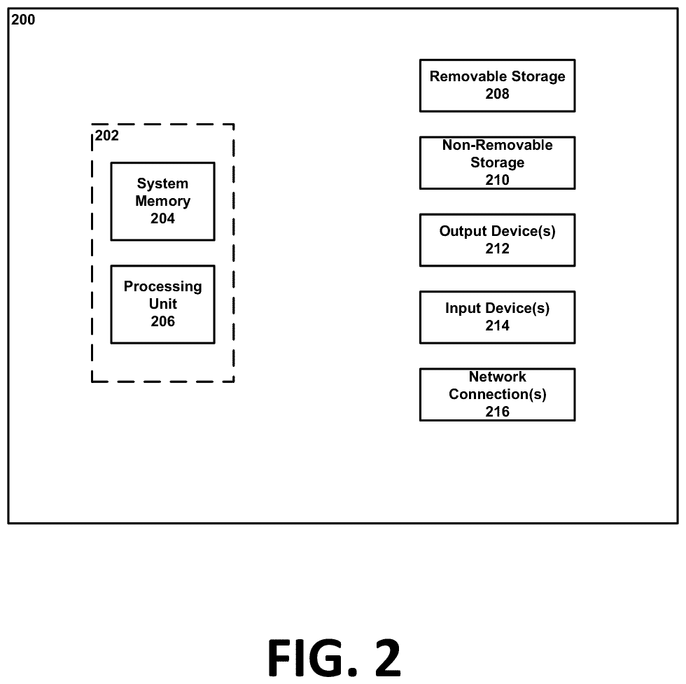

With reference to FIG. 1, a system block diagram representing an implementation of the present disclosure is illustrated. The system 100 can include a data recorder 107. The data recorder 107 can include a field programmable gate array (FPGA) 110 and a server 150. While the examples described herein refer to an FPGA 110, it should be understood that the systems and devices described herein can be implemented using other computing devices. For example, the FPGA 110 can be used in conjunction with, or replaced by another computing device. Optionally, an ASIC (application-specific integrated circuit) can be used to perform any or all of the functions of the FPGA 110 described herein. Alternatively or additionally, an SoC (system on a chip) can be used to perform any or all of the functions of the FPGA 110 described herein. Alternatively or additionally, the FPGA 110 can include at least a processor and memory and optionally any or all of the other components described with reference to the computing device 200 of FIG. 2.

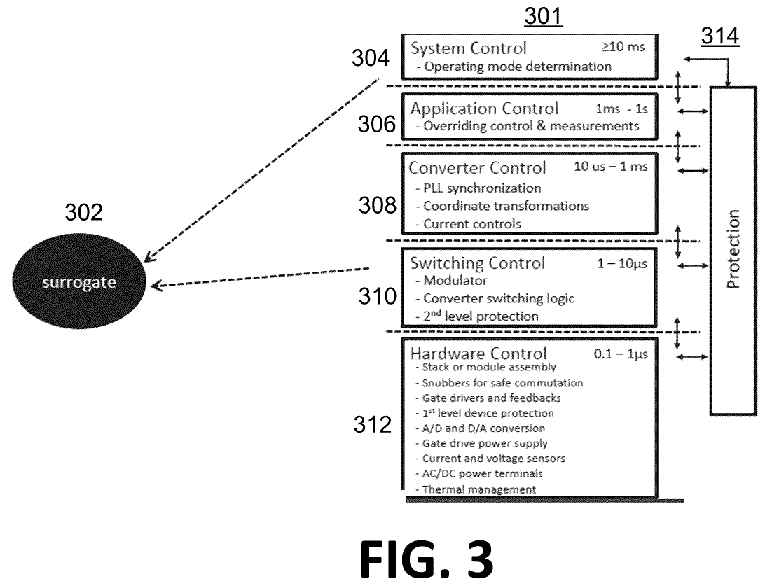

The system 100 can further include a power system. As shown in FIG. 1, the power system can be a power system simulator 120. An example power system simulator is shown and described herein with reference to FIG. 3. As used herein, a power system simulator is a specialized hardware (e.g. one or more digital processors) and software system to simulate and analyze the behavior of power systems in real-time, allowing engineers to study the dynamic behavior of complex electrical systems under various operating conditions. An example power system simulator is a real-time digital simulator (RTDS). An RTDS can create a virtual environment where the behavior of generators, transformers, transmission lines, loads, and other power system components can be modeled and studied. This simulation capability is particularly useful for testing and validating protection and control schemes, analyzing transient events, studying system stability, and testing new technologies before deploying them in real-world power systems. An example RTDS is the NOVACOR RTDS Simulator of RTDS Technologies Inc. of Winnipeg, Canada.

In some implementations, a hardware component is connected to the power system simulator (not shown). The hardware component can optionally be configured to perform a “controller hardware-in-the-loop” (CHIL) methodology. CHIL is a testing and simulation technique that can be used to test real hardware component(s) with simulated or virtual component(s) in a closed-loop configuration. CHIL can be used to test real hardware components under realistic conditions. As used herein, the real hardware components can be any hardware, including power system components. The simulated/virtual components can provide feedback to the real hardware components. By using simulated/virtual components, the operation of a real hardware component can be simulated in a large or expensive system without having to build a real copy of the system. CHIL can also avoid damaging real components, or creating unsafe conditions, which can be other concerns when a real hardware component is tested using a real system.

The power system simulator 120 can be coupled to the FPGA 110 so that data can be transmitted between the power system simulator 120 and the FPGA110. This disclosure contemplates that FPGA 110 and power system simulator 120 discussed above can be coupled through one or more communication links. This disclosure contemplates the communication links are any suitable communication link. For example, a communication link may be implemented by any medium that facilitates data exchange between the FPGA 110 and power system simulator 120 including, but not limited to, wired, wireless and optical links. In some implementations, the data transmitted between the power system simulator 120 and the FPGA 110 can be transmitted at least partially by a fiber optic cable 140. The FPGA 110 can be configured to record an output of the power system simulator 120 to a data file. Optionally, the power system simulator 120 includes a hardware simulation of a power system. A hardware simulation can be a real-time simulation of a physical power system, where, for example, 1 second of simulation time corresponds to one second of real time. In other words, a one minute simulation takes one minute to perform using a real-time hardware simulator.

As described above, the system 100 can further include a server 150 operably coupled to the FPGA 110. This disclosure contemplates that the FPGA 110 and server 150 discussed above can be coupled through one or more communication links. This disclosure contemplates the communication links are any suitable communication link. For example, a communication link may be implemented by any medium that facilitates data exchange between the FPGA 110 and server 150 including, but not limited to, wired, wireless and optical links. The server 150 can include one or more computing devices (for example, the computing device 200 shown in FIG. 2). The server 150 can be configured to receive the data file from the FPGA 110 and store the data file. Optionally, the server 150 is coupled to the FPGA 110 at least partially through an ethernet cable 152. In some implementations, the server 150 is configured to control the FPGA 110, for example by causing the FPGA 110 to start or stop recording data from the power system simulator 120.

In some implementations, the FPGA 110 can be triggered to record a frame of data based on a signal from the server 150. Optionally, the FPGA 110 can be configured to repeatedly record frames of data. In some implementations, the consecutive frames of data that are repeatedly recorded are separated by time delays of 50 microseconds or less.

In some implementations, the server 150 can be controlled and/or configured using an input system 180. Optionally, the input system 180 can include a trigger to cause the FPGA 110 to record data or to stop recording data, as described herein.

In some implementations, the system 100 can be configured to output data (e.g., data from one or more data frames) to a display (e.g., the output device 212 described in FIG. 2). The data or data frames can be output as representations (e.g., graphs, or tables) that show the data or data frames. As shown in FIG. 1, a messaging system 162 (e.g., ZeroMQ or ZMQ, as shown in FIG. 1) can be used to convert data from the server 150 to a visualization 172.

In some implementations, the system 100 can include a workstation 170. The workstation 170 can include any/all of the components shown and described with reference to the computing device 200 of FIG. 2. The workstation 170 can be configured to display data from one or more data files that were received by the server 150 from the FPGA 110.

In some implementations, the server 150 can include one or more multi-threaded processors (e.g., one or more of the processing units 206 shown in FIG. 2). The multi-threaded processors can be configured to simultaneously store (i.e., “log”) data from the FPGA 110, communicate with the FPGA 110, and process the data file. Optionally, the multi-threaded processors can be configured to simultaneously perform any two of the actions described herein (e.g., simultaneously communicate with the FPGA 110 and store data from the FPGA 110).

An example power system simulator system for testing, modeling, and developing control architecture is shown in FIG. 3. The system shown in FIG. 3 can be used as the power system simulator 120 described with reference to FIG. 1. The control architecture includes surrogate hardware 302 that can be configured as a power system simulator. The surrogate hardware 302 is operably coupled to control systems 301 (e.g., real or simulated controllers for a power system). As shown in FIG. 3, example control systems can include system control 304, application control 306, converter control 308, switching control 310, and/or hardware control 312. It should be understood that the control systems 301 shown in FIG. 3 are non-limiting examples and that any number and/or combination of control systems 301 can be used in implementations of the present disclosure. As also shown in FIG. 3, the example system can optionally include protection systems 314.

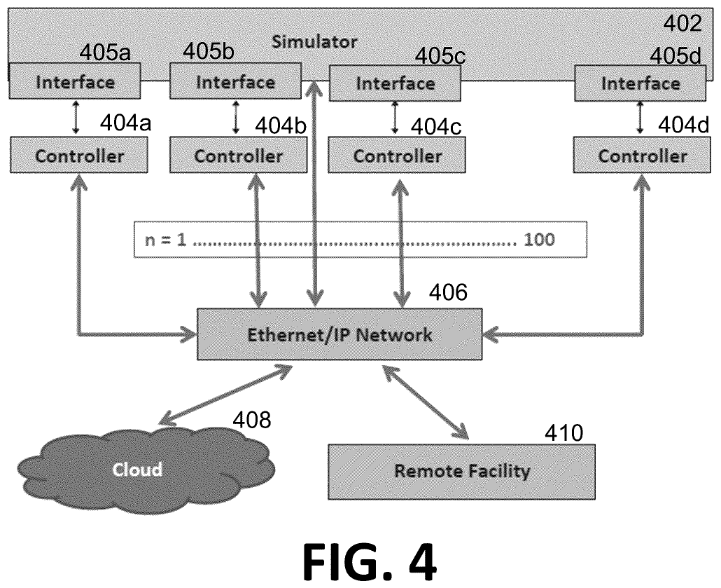

An example CHIL configuration is shown in FIG. 4. As shown in FIG. 4, CHIL can include a simulator 402 (e.g., the power system simulator 120 described with reference to FIGS. 1 and 3). The simulator can include interfaces 405a, 405b, 405c, 405d that operably couple the simulator to any number of controllers 404a, 404b, 404c, 404d, etc. The controllers can optionally include any of the control systems 301 described with reference to FIG. 3. As shown in FIG. 4, the controllers can be in operably communication by a network 406. The network 406 can optionally be in communication with remote devices (e.g., a server in a cloud 408, and/or a remote facility 410). The controllers 404a, 404b, 404c, 404d, network 406, cloud 408, and/or remote facility 410 can optionally be implemented using the computing device 200 described with reference to FIG. 2.

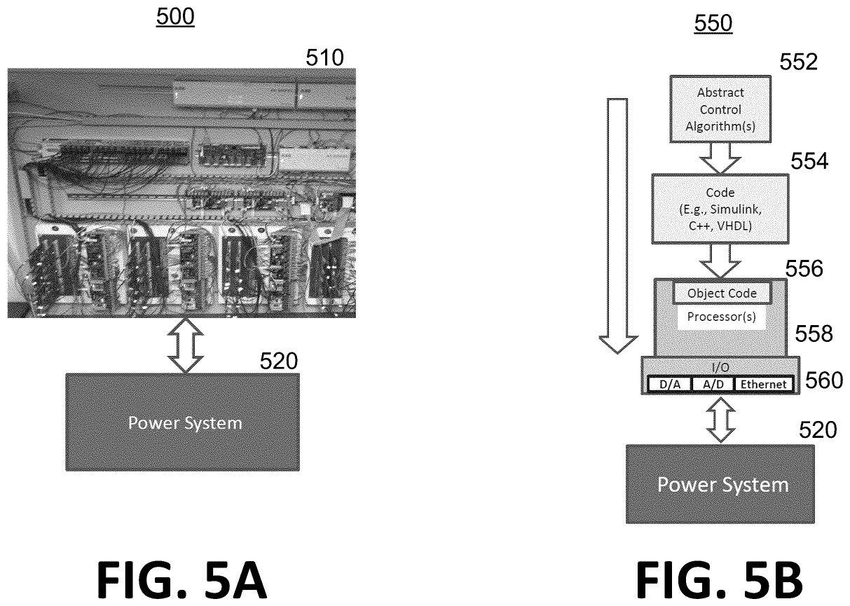

The present disclosure contemplates CHIL configurations other than the configuration described with reference to FIG. 4. As shown in FIG. 5A, the power system simulator 120 used in the system of FIG. 1 can be implemented using a “traditional” CHIL configuration 500, where a control algorithm is implemented on a field-deployed target platform 510 (e.g., a controller) and the field-deployed target platform 510 is operably coupled to a deployed power system 520.

As shown in FIG. 5B, the power system simulator 120 used in FIG. 1 can optionally be implemented using a “surrogate” CHIL configuration 550. In the surrogate CHIL configuration 550, control algorithms 552 can be implemented using software 554 (e.g., using any programming language or programming tools, such as Simulink, C++, VHDL). The software 554 can be implemented as compiled object code 556 on a processor 558. The processor 558 can include any or all of the components of the computing device 200 shown in FIG. 2. The processor 558 can be operably coupled to a power system 520 using any number of input/output device 560. Additional description of inputs and outputs that can be implemented in a computing device are described with reference to the input devices 214, output devices 212, and network connections 216 of FIG. 2.

It should be appreciated that the logical operations described herein with respect to the various figures may be implemented (1) as a sequence of computer implemented acts or program modules (i.e., software) running on a computing device (e.g., the computing device described in FIG. 2), (2) as interconnected machine logic circuits or circuit modules (i.e., hardware) within the computing device and/or (3) a combination of software and hardware of the computing device. Thus, the logical operations discussed herein are not limited to any specific combination of hardware and software. The implementation is a matter of choice dependent on the performance and other requirements of the computing device. Accordingly, the logical operations described herein are referred to variously as operations, structural devices, acts, or modules. These operations, structural devices, acts and modules may be implemented in software, in firmware, in special purpose digital logic, and any combination thereof. It should also be appreciated that more or fewer operations may be performed than shown in the figures and described herein. These operations may also be performed in a different order than those described herein.

Referring to FIG. 2, an example computing device 200 upon which the methods described herein may be implemented is illustrated. It should be understood that the example computing device 200 is only one example of a suitable computing environment upon which the methods described herein may be implemented. Optionally, the computing device 200 can be a well-known computing system including, but not limited to, personal computers, servers, handheld or laptop devices, multiprocessor systems, microprocessor-based systems, network personal computers (PCs), minicomputers, mainframe computers, embedded systems, and/or distributed computing environments including a plurality of any of the above systems or devices. Distributed computing environments enable remote computing devices, which are connected to a communication network or other data transmission medium, to perform various tasks. In the distributed computing environment, the program modules, applications, and other data may be stored on local and/or remote computer storage media.

In its most basic configuration, computing device 200 typically includes at least one processing unit 206 and system memory 204. Depending on the exact configuration and type of computing device, system memory 204 may be volatile (such as random access memory (RAM)), non-volatile (such as read-only memory (ROM), flash memory, etc.), or some combination of the two. This most basic configuration is illustrated in FIG. 2 by dashed line 202. The processing unit 206 may be a standard programmable processor that performs arithmetic and logic operations necessary for operation of the computing device 200. The computing device 200 may also include a bus or other communication mechanism for communicating information among various components of the computing device 200.

Computing device 200 may have additional features/functionality. For example, computing device 200 may include additional storage such as removable storage 208 and non-removable storage 210 including, but not limited to, magnetic or optical disks or tapes. Computing device 200 may also contain network connection(s) 216 that allow the device to communicate with other devices. Computing device 200 may also have input device(s) 214 such as a keyboard, mouse, touch screen, etc. Output device(s) 212 such as a display, speakers, printer, etc. may also be included. The additional devices may be connected to the bus in order to facilitate communication of data among the components of the computing device 200. All these devices are well known in the art and need not be discussed at length here.

The processing unit 206 may be configured to execute program code encoded in tangible, computer-readable media. Tangible, computer-readable media refers to any media that is capable of providing data that causes the computing device 200 (i.e., a machine) to operate in a particular fashion. Various computer-readable media may be utilized to provide instructions to the processing unit 206 for execution. Example tangible, computer-readable media may include, but is not limited to, volatile media, non-volatile media, removable media and non-removable media implemented in any method or technology for storage of information such as computer readable instructions, data structures, program modules or other data. System memory 204, removable storage 208, and non-removable storage 210 are all examples of tangible, computer storage media. Example tangible, computer-readable recording media include, but are not limited to, an integrated circuit (e.g., field-programmable gate array or application-specific IC), a hard disk, an optical disk, a magneto-optical disk, a floppy disk, a magnetic tape, a holographic storage medium, a solid-state device, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices.

In an example implementation, the processing unit 206 may execute program code stored in the system memory 204. For example, the bus may carry data to the system memory 204, from which the processing unit 206 receives and executes instructions. The data received by the system memory 204 may optionally be stored on the removable storage 208 or the non-removable storage 210 before or after execution by the processing unit 206.

It should be understood that the various techniques described herein may be implemented in connection with hardware or software or, where appropriate, with a combination thereof. Thus, the methods and apparatuses of the presently disclosed subject matter, or certain aspects or portions thereof, may take the form of program code (i.e., instructions) embodied in tangible media, such as floppy diskettes, CD-ROMs, hard drives, or any other machine-readable storage medium wherein, when the program code is loaded into and executed by a machine, such as a computing device, the machine becomes an apparatus for practicing the presently disclosed subject matter. In the case of program code execution on programmable computers, the computing device generally includes a processor, a storage medium readable by the processor (including volatile and non-volatile memory and/or storage elements), at least one input device, and at least one output device. One or more programs may implement or utilize the processes described in connection with the presently disclosed subject matter, e.g., through the use of an application programming interface (API), reusable controls, or the like. Such programs may be implemented in a high level procedural or object-oriented programming language to communicate with a computer system. However, the program(s) can be implemented in assembly or machine language, if desired. In any case, the language may be a compiled or interpreted language and it may be combined with hardware implementations.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary and are not intended to limit the disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

An example implementation of the present disclosure includes data recorders that can be used in simulators of power systems. The example implementation can be used with a variety of different hardware and/or software simulation systems, non-limiting examples of which include: real-time digital simulator (RTDS); PHIL (Power Hardware-in-the-Loop); CHIL (controller hardware-in-the-loop) and co-simulation. As used herein, co-simulation refers to separately simulating/modeling multiple systems in a coupled problem (e.g., two or more subsystems) and exchanging data between the co-simulated subsystems. The example implementation can be implemented using the system 100 of FIG. 1.

The example implementation can, be used for fault recording, and demonstration, as well as characterizing models and/or devices in a system. For example, the data recorders described herein with respect to FIG. 1 can be used with real-time simulator software (e.g., software sold under the trade name RTDS). Simulator software can be configured to acquire data that can be used to plot system performance (e.g., using software sold under the trade name RSCAD). Additionally, implementations of the present disclosure can be configured to be controlled by software (e.g., RSCAD) to determine what data is recorded. Alternatively or additionally, the example implementation of the present disclosure can stream data to a server or to any other computer.

Optionally, the example implementation can record data over any time interval. Example time intervals include minutes, hours, and days. For example, implementations described herein can record data over a period from 1-24 hours.

Additionally implementations of the present disclosure can be configured to record data at different sampling rates and/or variable sampling rates. For example, different recorded signals can include different sampling rates. Additionally, sampling can be based on manual triggers (e.g., by user input), by detected fault events, by pre-triggers, and/or by continuous sampling.

Alternatively or additionally, implementations of the present disclosure can interact with a software runtime (e.g., a commercial software for plotting or simulating a power system such as RSCAD or RTDS). Implementations of the present disclosure can optionally be configured to reduce data rates to avoid traffic congestion.

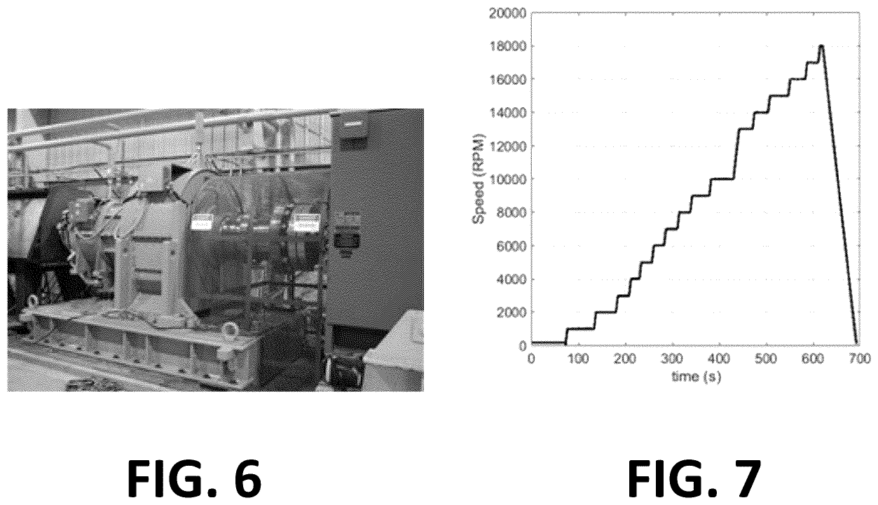

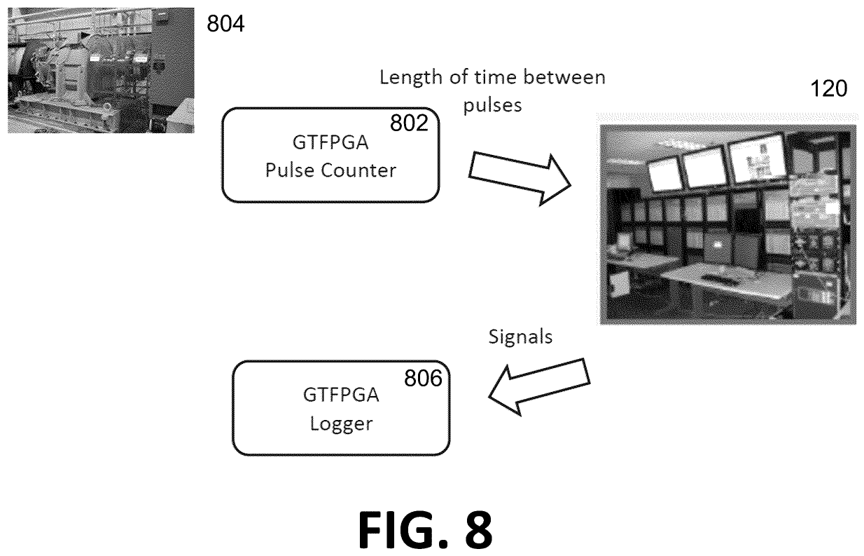

An example study was performed using a 5MW dynamometer and gear box, illustrated in FIG. 6. As shown in the plot illustrated in FIG. 7, the example system can record the RPM over time for the dynamometer and gear box in operation. An example system overview for a study is shown in FIG. 8. The system includes a pulse counter 802 configured to measure a 5MW dynamometer 804, and a logger 806 configured to measure signals from a power system simulator 120.

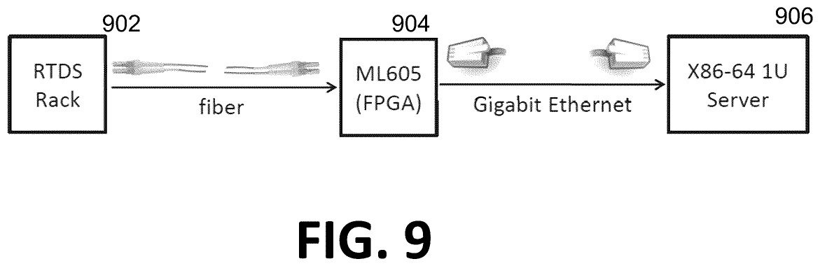

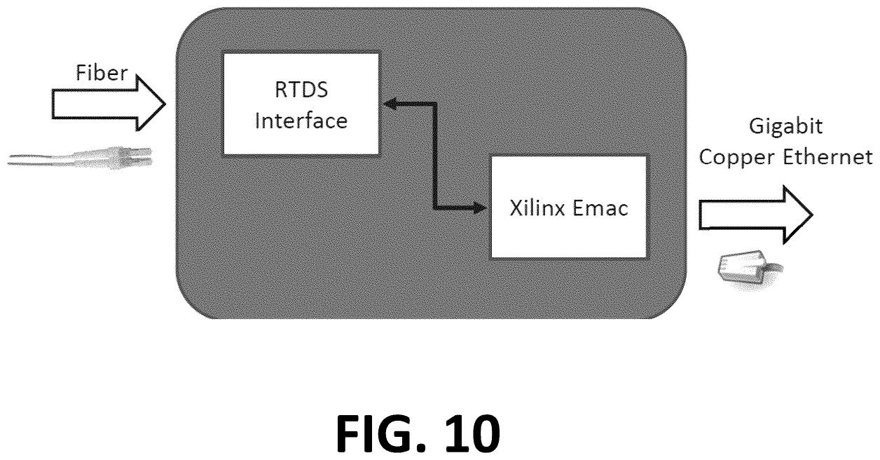

The logger 806 can optionally be implemented using an FPGA and/or simulation hardware (e.g., simulation hardware sold under the trade name GTFPGA). FIG. 9 illustrates a schematic of a logger implemented using a rack mounted simulator 902 (e.g., an RTDS simulator) coupled to an FPGA 904 (e.g., an FPGA sold under the trade name ML605 Xilinx) and a server 906 (e.g., a server running Python/Cthon, C++ and/or SSH). While the connections shown in FIG. 9 are shown as fiber and gigabit ethernet connections, it should be understood that any network connections can be used in various implementations of the present disclosure. As shown in FIG. 10, implementations of the present disclosure can optionally include fiber to ethernet conversion.

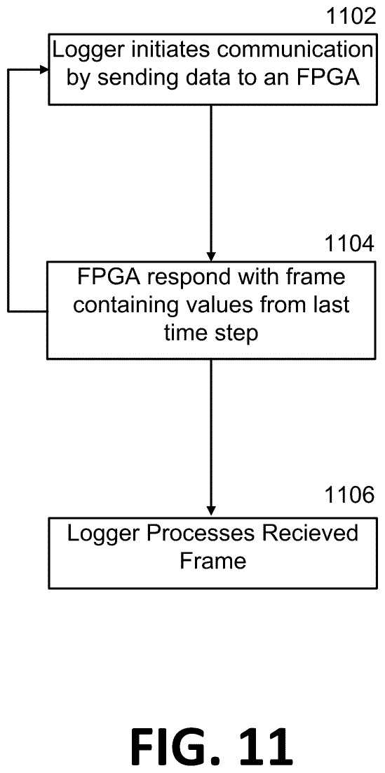

An example communication protocol is shown in FIG. 11. At step 1102, a logger can initiate communication by sending data to an FPGA. At step 1104, an FPGA (e.g., a GTFPGA) can respond with a frame containing values from a latest time step (e.g., a simulation time step). Optionally step 1104 can be repeated every time step. At step 1106, the logger can process a received frame. Optionally, the frame can be processed in approximately 50 microseconds. Processing the frame can optionally include determining if data should be logged, checking for missing time steps in the data, formatting data for storage, writing data to a disk, and/or writing messages to a display.

Optionally, the logger can be implemented using isolated cores of a processor, with process threads pinned to each core. Optionally hyperthreaded cores are disabled. By limiting each software thread to a specific hardware core of the processor, the time to execute each operation can be deterministic/predictable, and the priorities of different operations in the logger can be selected.

To operate the example system, the user can optionally create a “signal list file” that specifies signals to be captured by the logger. A script can be configured to read the signal list file and configure the FPGA for capture of the selected signals. The script can be configured to cause the signal list file to be transmitted to the logger. During operation, the logger can generate and store a file in memory with the recorded signals. Optionally, the file is a CSV file, and can include the signal names and any/all of the recorded data. The user can control the starting and/or stopping of recording of data using a signal provided at runtime. Optionally, the signal can be an RTDS signal (e.g., a runtime switch). Alternatively or additionally, a config file can be created that sets sampling rate and/or any other sampling parameters for the capture of the selected signals.

The present disclosure contemplates that different file types and structures can be used by the systems described herein. For example, text format scan optionally be used (e.g., CSV files). Text formats can be human readable. Alternatively or additionally, a binary file type can be used (e.g., a MATLAB file format). Binary file formats can include increased performance, but may not be human readable and may be more difficult to manipulate.

In some implementations of the present disclosure, concurrent RTDS racks and/or chassis can be logged concurrently. The present disclosure also contemplates that the logger and/or FPGA can be operably coupled to a network for online analysis, control, and/or visualization. The present disclosure further contemplates that the simulation and surrogate hardware can be in bi-directional communication during operation.

What is claimed:

1. A data recorder, comprising:
a field programmable gate array (FPGA) operably coupled to a power system simulator; the FPGA configured to record an output of the power system simulator to a data file; and
a server operably coupled to the field programmable gate array; wherein the server is configured to receive the data file from the FPGA and store the data file.

2. The data recorder of claim 1, wherein the power system simulator is a real-time digital simulator (RTDS).

3. The data recorder of claim 1, wherein the power system simulator is configured to perform a real-time hardware simulation.

4. The data recorder of claim 1, wherein the FPGA is operably coupled to the power system simulator by a fiber optic cable.

5. The data recorder of claim 1, wherein the FPGA is operably coupled to the server by an ethernet cable.

6. The data recorder of claim 1, further comprising a workstation, wherein the workstation is operably coupled to the server.

7. The data recorder of claim 1, wherein the FPGA is configured to record a frame based on a signal from the server.

8. The data recorder of claim 7, wherein a delay between consecutive frames is 50 microseconds or less.

9. The data recorder of claim 7, wherein the FPGA is configured to output a representation of the frame to a display.

10. The data recorder of claim 1, wherein the server comprises a multi-threaded processor configured to simultaneously log data, communicate with the FPGA, and process the data file.

11. The data recorder of claim 1, wherein a hardware component is operably coupled to the power system simulator.

12. A system comprising:
a power system simulator;
a field programmable gate array (FPGA) operably coupled to the power system simulator; the FPGA configured to record an output of the power system simulator to a data file; and
a server operably coupled to the field programmable gate array; wherein the server is configured to receive the data file from the FPGA and store the data file.

13. The system of claim 12, wherein the power system simulator is a real-time digital simulator (RTDS).

14. The system of claim 12, wherein the power system simulator is configured to perform a real-time hardware simulation.

15. The system of claim 12, further comprising a workstation, wherein the workstation is operably coupled to the server.

16. The system of claim 12, wherein the FPGA is configured to record a frame based on a signal from the server.

17. The system of claim 15, wherein a delay between consecutive frames is 50 microseconds or less.

18. The system of claim 15, wherein the server is configured to output a representation of a frame to a display.

19. The system of claim 12, wherein the server comprises a multi-threaded processor configured to simultaneously log data, communicate with the FPGA, and process the data file.

20. The system of claim 12, further comprising a hardware component operably coupled to the power system simulator.
